(19) United States
(12) Patent Application Publication
(10) Pub. No.: US 2025/0089373 A1
(43) Pub. Date: Mar. 13, 2025

(54) ARRAY SUBSTRATE AND DISPLAY APPARATUS

(71) Applicants: Ordos Yuansheng Optoelectronics Co., Ltd., Ordos, Inner Mongolia (CN); BOE Technology Group Co., Ltd., Beijing (CN)

(72) Inventors: Hong Liu, Beijing (CN); Jianyun Xie, Beijing (CN); Jingyi Xu, Beijing (CN); Zhenhong Xiao, Beijing (CN)

(73) Assignees: Ordos Yuansheng Optoelectronics Co., Ltd., Ordos, Inner Mongolia (CN); BOE Technology Group Co., Ltd., Beijing (CN)

(21) Appl. No.: 18/701,381

(22) PCT Filed: Apr. 28, 2023
(86) PCT No.: PCT/CN2023/091822

§ 371 Date: Apr. 15, 2024

(30) Foreign Application Priority Data
May 30, 2022 (CN) 202210612206.4

(51) Int. Cl. H01L 27/12; G02F 1/1362

(52) U.S. Cl. CPC H10D 86/60; G02F 1/136286; H10D 86/441

(57) ABSTRACT

An array base plate and a display apparatus are provided by the present application. The array base plate includes a substrate, an active area and a binding area that are located on the substrate, wherein the binding area is located at one side of the active area; the array base plate further includes: an alignment layer extending from the active area to the binding area; and binding terminals located in the binding area, wherein an orthographic projection of the alignment layer on the substrate does not overlap with orthographic projections of the binding terminals on the substrate; wherein in a direction parallel to a plane where the substrate is located and pointing from the active area to the binding area.

### CROSS REFERENCE TO RELATED APPLICATIONS

The present application claims the priority of the Chinese patent application filed on May 30, 2022 before the Chinese Patent Office with the application number of 202210612206.4 and the title of “ARRAY SUBSTRATE AND DISPLAY APPARATUS”, which is incorporated herein in its entirety by reference.

### TECHNICAL FIELD

The present disclosure relates to the technical field of displaying and, more particularly, to an array base plate, and a preparing method for the array base plate and an encoded pattern.

### BACKGROUND

With the rapid development of a display technology, narrow-border display has gradually become a popular focus in the market. However, in a display product in the related art, due to the arrangement of wirings in a binding area of the display product is dense, it is difficult to reduce a size of the display product, so that a size of a border frame at a side provided with the binding area in the display product cannot be further reduced.

### SUMMARY

Embodiments of the present disclosure adopt the following technical solutions:

In a first aspect, an array base plate is provided by the embodiments of the present application, which includes a substrate, an active area and a binding area that are located on the substrate, wherein the binding area is located at one side of the active area;
the array base plate further including:
an alignment layer extending from the active area to the binding area; and
binding terminals located in the binding area, wherein an orthographic projection of the alignment layer on the substrate does not overlap with orthographic projections of the binding terminals on the substrate;
wherein in a direction parallel to a plane where the substrate is located and pointing from the active area to the binding area, a minimum distance from the binding terminals to an edge of the active area is less than or equal to a maximum distance from an edge of a part, located in the binding area, of the alignment layer to the edge of the active area.

In some embodiments of the present application, the array base plate includes a connecting layer located in the binding area, the connecting layer covers surfaces of sides of the binding terminals away from the substrate, and extends to an area other than the binding terminals, and an orthographic projection of the connecting layer on the substrate partially overlaps with an orthographic projection of the part, located in the binding area, of the alignment layer on the substrate.

In some embodiments of the present application, the binding area includes a first binding subarea and a second binding subarea, the first binding subarea is located between the second binding subarea and the active area, parts of the binding terminals are located in the first binding subarea, and parts of the binding terminals are located in the second binding subarea;
wherein the orthographic projection of the connecting layer on the substrate overlaps with an orthographic projection of a part, located at a side where the first binding subarea is away from the second binding subarea, of the alignment layer on the substrate.

In some embodiments of the present application, the array base plate further includes a planarization layer extending from the active area to the binding area, a part, disposed in the binding area, of the planarization layer is located between the connecting layer and the substrate; a part, located in the first binding subarea, of the planarization layer is provided with a first groove, and a part, located in the second binding subarea, of the planarization layer is provided with a second groove;
the first groove is disconnected from the second groove, all the binding terminals in the first binding subarea are located in the first groove, all the binding terminals in the second binding subarea are located in the second groove, and an area between an orthographic projection of an outer contour of the first groove on the substrate and an orthographic projection of an outer contour of the second groove on the substrate does not overlap with the orthographic projection of the alignment layer on the substrate.

In some embodiments of the present application, an area defined by orthographic projections of outer contours of all grooves on the substrate at least partially overlaps with the orthographic projection of the connecting layer on the substrate, and the area defined by the orthographic projections of the outer contours of all the grooves on the substrate does not overlap with the orthographic projection of the alignment layer on the substrate.

In some embodiments of the present application, the planarization layer is further provided with third grooves, the third grooves communicate with the first groove, the third grooves extend along a direction away from the first binding subarea along a first direction, and the first direction is perpendicular to a direction pointing from the active area to the binding area; and along the direction pointing from the active area to the binding area, sizes of orthographic projections of the third grooves on the substrate are less than a size of an orthographic projection of the first groove on the substrate.

In some embodiments of the present application, the area defined by the orthographic projection of the outer contour of the first groove on the substrate and the area defined by the orthographic projection of the outer contour of the second groove on the substrate are both located in the orthographic projection of the connecting layer on the substrate; and
an area defined by orthographic projections of outer contours of the third grooves on the substrate partially overlaps with the orthographic projection of the connecting layer on the substrate.

In some embodiments of the present application, along a direction parallel to the plane where the substrate is located and along the first direction, a minimum distance from ends, away from the first groove, of the third grooves to an edge of the connecting layer is greater than or equal to 300 μm and is less than or equal to 800 μm.

In some embodiments of the present application, the array base plate includes a fan-out area located between the active area and the binding area; the array base plate further includes connecting wrings, the connecting wrings extend from the fan-out area to the binding area, parts, located in the binding area, of the connecting wrings are disposed in areas other than the first binding subarea and the second binding subarea in the binding area, and the connecting wrings are electrically connected to the binding terminals; and the area defined by the orthographic projections of the outer contours of the third grooves on the substrate overlaps with orthographic projections of parts of the connecting wrings on the substrate.

In some embodiments of the present application, the array base plate further includes a gate layer and a source-drain metal layer, the gate layer is insulated from the source-drain metal layer; the source-drain metal layer is located between the planarization layer and the substrate, and the gate layer is located between the source-drain metal layer and the substrate;
parts of the connecting wrings include first line segments and second line segments, the first line segments are located at the gate layer, and the second line segments are located at the source-drain metal layer;
wherein orthographic projections of the first line segments on the substrate are located in the area defined by the orthographic projections of the outer contours of the third grooves on the substrate, orthographic projections of the second line segments on the substrate are located out of the area defined by the orthographic projections of the outer contours of the third grooves on the substrate, and the first line segments are electrically connected to the second line segments.

In some embodiments of the present application, the second line segments include first subline segments and second subline segments, the orthographic projections of the first line segments on the substrate are located between orthographic projections of the first subline segments on the substrate and orthographic projections of the second subline segments on the substrate; and the first subline segments are electrically connected to the second subline segments by using the first line segments;
wherein the second subline segments are located at sides, away from the active area, of the first subline segments, and the orthographic projection of the alignment layer on the substrate overlaps with the orthographic projections of the first subline segments on the substrate, and the orthographic projection of the alignment layer on the substrate does not overlap with orthographic projections of at least part of the second subline segments on the substrate.

In some embodiments of the present application, the array base plate further includes at least one conductive pattern, the at least one conductive pattern is located between the binding terminals and the connecting wrings, and an orthographic projection of the at least one conductive pattern on the substrate is located in the area defined by the orthographic projection of the outer contour of the first groove on the substrate.

In some embodiments of the present application, the area defined by the orthographic projections of the outer contours of all the grooves on the substrate is located in the orthographic projection of the connecting layer on the substrate.

In some embodiments of the present application, a minimum distance from all the binding terminals arranged along a side wall of the first groove in the first binding subarea to the side wall of the first groove is less than or equal to a first preset value, a minimum distance from all the binding terminals arranged along a side wall of the second groove in the second binding subarea to the side wall of the second groove is less than or equal to the first preset value, and the first present value is a process deviation value.

In some embodiments of the present application, a distance from a surface, away from the substrate, of a part, covering the binding terminals, of the connecting layer to the substrate along a direction perpendicular to the plane where the substrate is located is less than a distance from a surface, away from the substrate, of the rest part of the connecting layer to the substrate along the direction perpendicular to the plane where the substrate is located.

In some embodiments of the present application, the planarization layer is further provided with at least one fourth groove, the at least one fourth groove is disconnected from the first groove, the array base plate further includes at least one conductive pattern located in the binding area, one conductive pattern is disposed in one fourth groove, and a distance from the at least one conductive pattern to a side wall of each of the at least one fourth groove is less than or equal to the first preset value.

In some embodiments of the present application, the planarization layer is provided with two fourth grooves located at a same side of the first groove, and a direction pointing from the first groove to each of the two fourth grooves is perpendicular to the direction pointing from the active area to the binding area; and
an orthographic projection of a part, located between two adjacent fourth grooves, of the planarization layer on the substrate overlaps with the orthographic projection of the alignment layer on the substrate.

In a second aspect, a display apparatus is provided by the embodiments of the present application, which includes the array base plate stated above.

In some embodiments of the present application, the display apparatus further includes a driver chip, the driver chip is electrically connected to the binding terminals by using the connecting layer, the connecting layer includes an anisotropic conductive film, and an orthographic projection of the driver chip on the substrate is located in the orthographic projection of the connecting layer on the substrate.

In some embodiments of the present application, the display apparatus further includes a flexible printed circuit, the flexible printed circuit is electrically connected to a binding electrode on the array base plate by using a conductive layer, and the conductive layer includes an anisotropic conductive film.

In some embodiments of the present application, the display apparatus further includes an opposite base plate, the opposite base plate is opposite to the array base plate, and an orthographic projection of the opposite base plate on the substrate does not overlap with the binding area.

The above description is only an overview of the technical solution of the present disclosure, in order to be able to better understand the technical means of the present disclosure, and the solution can be implemented in accordance with the content of the description, and in order to make the above and other purposes, features and advantages of the present disclosure more obvious and easy to understand, the following specific embodiments of the present disclosure are hereby given.

### BRIEF DESCRIPTION OF THE DRAWINGS

In order to describe the technical solutions in embodiments of the present disclosure or the related art more clearly, the drawings required to be used to describe the embodiments or the related art will be briefly introduced below. Apparently, the drawings in the following description show only some embodiments of the present disclosure, and a person skilled in the art can obtain other figures according to these figures without paying creative work.

FIG. 1, FIG. 4A and FIG. 4B are schematic structural diagrams of three array base plates in related art; wherein FIG. 4B is a sectional diagram of FIG. 4A along an M1M12 direction;

FIG. 2 and FIG. 3 are schematic structural diagrams of binding areas of two narrow-border array base plates provided in the embodiments of the present disclosure; and

FIG. 5 to FIG. 14 are schematic design diagrams of groove structures of binding areas of ten array base plates provided in the embodiments of the present disclosure.

### DETAILED DESCRIPTION OF THE EMBODIMENTS

The technical solutions in the embodiments of the present disclosure will be described clearly and completely below in conjunction with the drawings in the embodiments of the present disclosure. Apparently, the described embodiments are only a part of the embodiments of the present disclosure, but not all of the embodiments. Based on the embodiments of the present disclosure, all other embodiments obtained by those of ordinary skill in the art without creative efforts shall fall within the protection scope of the present disclosure.

In the figures, for clarity, the thickness of areas and layers may be exaggerated. The same reference numerals in the drawings represent the same or similar structures, and therefore, detailed descriptions thereof will be omitted. In addition, the drawings are only exemplary illustrations of the present disclosure, but are not drawn according to a certain proportion.

In the embodiments of the present disclosure, “a plurality of” means two or more unless specifically defined otherwise. A directional or positional relationship indicated by the term “upper” is based on the drawings, and is only intended to facilitate describing the present disclosure and simplify the description, rather than to indicate or imply that an appointed structure or element has to be located in a specific direction or structured and operated in the specific direction so as not to be understood as a limitation on the present disclosure.

In the overall specification and the claims, the term “including” is interpreted as open inclusion, i.e. “including, but not limited to” unless it is required in the context otherwise. In the description of the specification, the term “an embodiment”, “some embodiments”, “exemplary embodiments”, “examples”, “specific examples” or “some examples” is intended to indicate that specific features, structures, materials or characteristics related to this embodiment or example are included in at least one embodiment or example of the present disclosure. The schematic indication of the above-mentioned terms does not necessarily refer to the same embodiment or example. In addition, the specific features, structures, materials or characteristics can be included in any one or more embodiments or examples in any proper way.

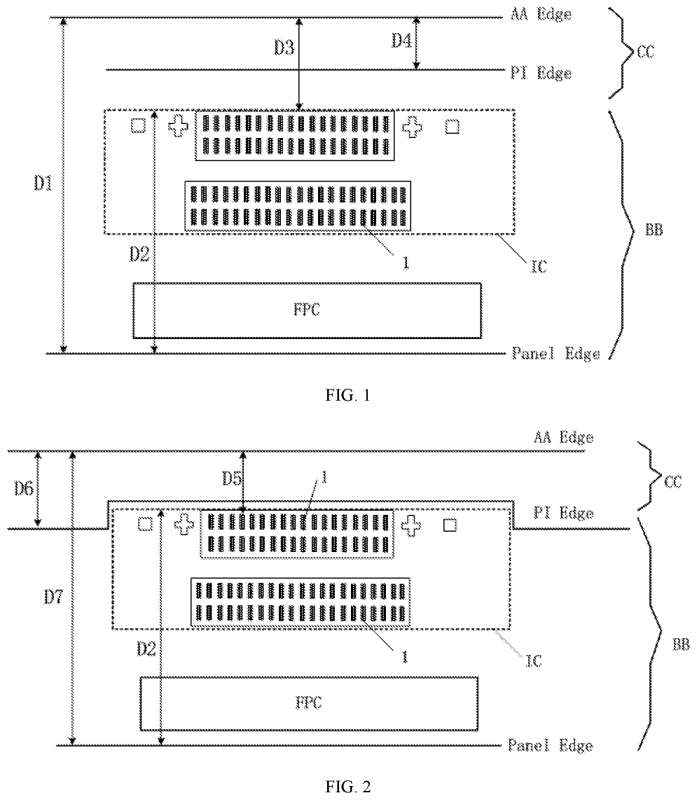

With the rapid development of a display technology, a display product with an extremely narrow border frame has become a hot spot focused by customers. In the related art, as shown in FIG. 1, an edge PI Edge of an alignment layer in a display panel is located between an edge AA Edge of an active area and an upper edge of a driver chip IC in a binding area BB, moreover, a distance D3 from the edge PI Edge of the alignment layer to the upper edge of the driver chip IC along a direction pointing from the active area AA to the binding area BB is usually about 1.57 mm, a distance D4 from the edge PI Edge of the alignment layer to the edge AA Edge of the active area is usually about 0.6 mm-1.2 mm, a distance D2 from the upper edge of the driver chip IC to an edge Panel Edge of the display panel is usually about 1.57 mm, and thus, a distance D1 (a size of a lower border frame) from the edge AA Edge of the active area to the edge Panel Edge of the display panel ranges from 2.8 mm to 3.2 mm.

In addition, in the related art, as shown in FIG. 1 and FIG. 4A, a groove K1 is disposed in a planarization layer PLN in the binding area BB, so that all binding terminals at an output end are disposed in the groove K1; the driver chip IC is disposed on the binding terminals and is electrically connected to the binding terminals; during the preparation the alignment layer, when a process is instable or an anomaly occurs, an alignment material PI flowing to the binding area BB flows around an edge of the groove K1, so that the alignment material PI does not cover the binding terminals at the output end. In the related art, in order to relieve an abnormal flow direction of the alignment material PI, a certain distance is set between the edge PI Edge of the alignment layer and the upper edge of the driver chip IC, which is not beneficial to the design and preparation of a display product with a narrow border.

Based on this, an array base plate is provided by an embodiment of the present disclosure, with reference to FIG. 2, including: a substrate, an active area AA and a binding area BB that are located on the substrate, wherein the binding area BB is located at one side of the active area AA; the array base plate further includes:
an alignment layer PI extending from the active area AA to the binding area BB; and
binding terminals 1 located in the binding area BB, wherein an orthographic projection of the alignment layer PI on the substrate does not overlap with orthographic projections of the binding terminals 1 on the substrate;
wherein in a direction parallel to a plane where the substrate is located and pointing from the active area AA to the binding area BB, a minimum distance D5 from the binding terminals 1 to an edge of the active area AA is less than or equal to a maximum distance D6 from an edge PI Edge of a part, located in the binding area BB, of the alignment layer PI to the edge AA Edge of the active area.

A dotted box marked with IC in FIG. 1 and FIG. 2 refers to an area defined by an outer contour of the driver chip after the driver chip is soldered, and is only used for description.

It should be noted that, during actual applications, the array base plate includes the active area AA and a peripheral area surrounding the active area, the peripheral area includes at least one binding area BB, wherein a fan-out area CC can be further disposed between the active area AA and the binding area BB.

The above-mentioned extending from the active area AA to the binding area BB can be understood as extending from the active area AA to the fan-out area CC and then to the binding area BB. Meanings in the following related descriptions are similar to those described herein so as to be no longer repeated.

In addition, in the related drawings of the array base plate provided in the embodiment of the present disclosure, an area marked with a flexible printed circuit (FPC) refers to an area defined by an outer contour of the bound FPC after the FPC is bound.

Herein, a specific structure in the active area AA of the array base plate is not limited, and can be specifically determined according to an actual situation.

Herein, a specific structure and quantity of the binding terminals 1 in the binding area BB are not limited, and can be specifically determined according to an actual design.

In an exemplary embodiment, the minimum distance D5 from the binding terminals 1 to the edge of the active area AA refers to a distance from the binding terminal 1 closest to the active area AA in all the binding terminals 1 to the edge of the active area AA along the direction pointing from the active area AA to the binding area BB.

Exemplarily, D5 ranges from 0.5 mm to o 1.1 mm, such as 1.05 mm or 1.06 mm.

In an exemplary embodiment, the maximum distance D6 from the edge PI Edge of the part, located in the binding area BB, of the alignment layer PI to the edge AA Edge of the active area refers to a distance from a part, farthest from the edge AA Edge of the active area, of the edge PI Edge of the alignment layer to the edge of the active area AA along the direction pointing from the active area AA to the binding area BB.

Exemplarily, D6 ranges from 0.6 mm to 1.2 mm, such as 1.1 mm or 1.06 mm.

During actual applications, as shown in FIG. 2, since the alignment layer PI is set to bypass an area where the binding terminals 1 are located, the part, farthest from the edge AA Edge of the active area, of the edge PI Edge of the alignment layer is usually located at two sides of the area where the binding terminals 1 are located.

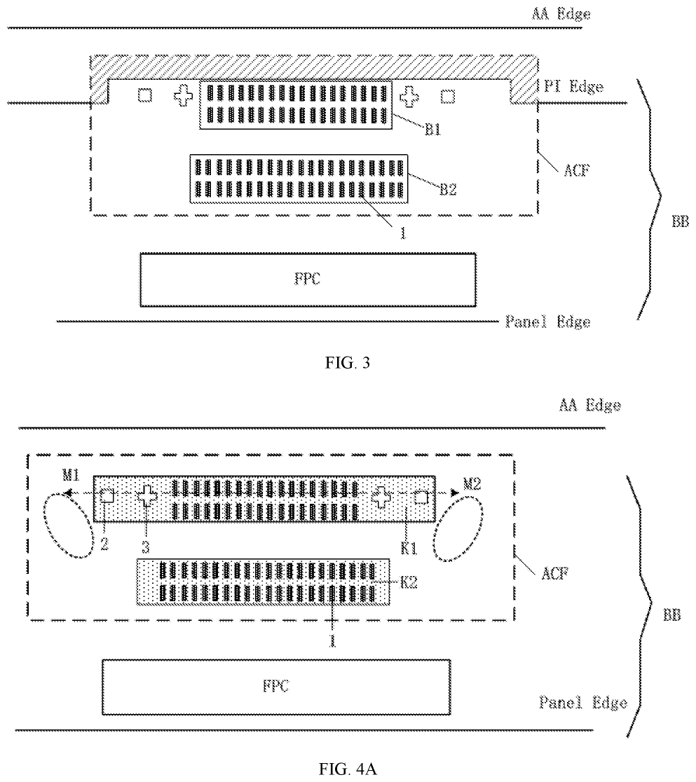

As shown in FIG. 2 and FIG. 3, in the embodiment of the present disclosure, the alignment layer PI is set to extend to the binding area BB and bypass the area where the binding terminals 1 are located, therefore, along the direction parallel to the plane where the substrate is located and pointing from the active area AA to the binding area BB, the minimum distance D5 from the binding terminals 1 to the edge of the active area AA is less than or equal to the maximum distance D6 from the edge PI Edge of the part, located in the binding area BB, of the alignment layer PI to the edge AA Edge of the active area. In this way, on one hand, the situation that the alignment layer PI covers the binding terminals 1 to affect normal conduction between the binding terminals 1 and the driver chip is avoided, and on the other hand, a distance from the area where the binding terminals 1 are located to the active area AA along the direction pointing from the active area AA to the binding area BB can be shortened to a great extent, thereby it is beneficial to the reduction of a size of a border frame of a side where the binding area BB of a display apparatus is located.

It should be noted that, during actual applications, the edge PI Edge of the alignment layer is not completely a straight line segment. Due to the flowability of the material of alignment layer PI, an arc will appear on an edge of the alignment layer PI. The edge PI Edge of the alignment layer in the drawings provided in the embodiment of the present disclosure only illustrates a contour position of the alignment layer.

In addition, as shown in FIG. 2, the distance D2 from the upper edge of the driver chip IC of the array base plate provided in the embodiment of the present disclosure to the edge Panel Edge of the array base plate may range from 1.4 mm to 1.6 mm, such as about 1.57 mm. In conjunction with the size of the minimum distance D5 from the binding terminals 1 to the edge of the active area AA, it can be known by actual tests and measurement that a distance D7 (a size of a lower border frame) from the edge AA Edge of the active area of the array base plate provided in the embodiment of the present disclosure to the edge Panel Edge of the array base plate ranges from 2.4 mm to 2.8 mm, such as about 2.5 mm. Apparently, compared with a size of a lower border frame of the array base plate in the related art, a size of a border frame at a side where the binding area of the array base plate provided in the embodiment of the present disclosure is located is reduced to a great extent, so that a product with an extremely narrow border frame can be prepared.

It should be noted that, in embodiments of the present disclosure, the description related to “about” refers to a fluctuation value of a related size within a process allowed range, and a fluctuation range thereof can be determined according to differences in actual processes so as to be no longer limited.

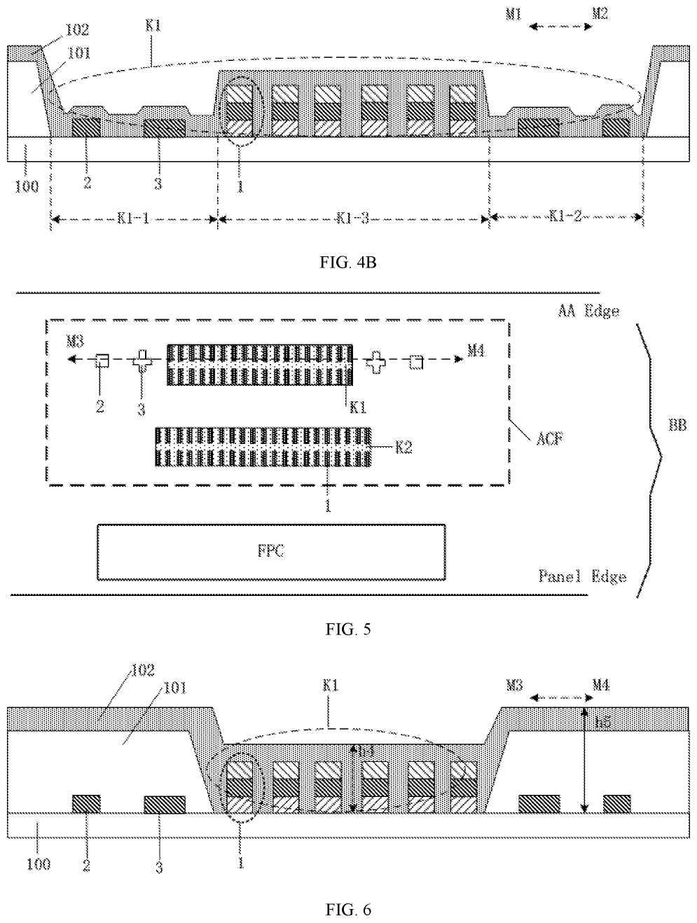

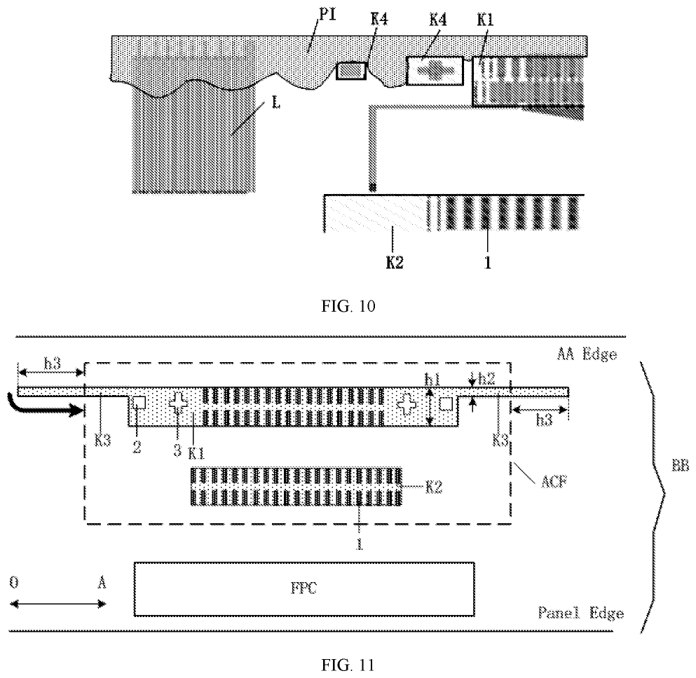

In some embodiments of the present disclosure, as shown in FIG. 3, FIG. 5, FIG. 6, FIG. 10, and FIG. 11, the array base plate includes a connecting layer 102 located in the binding area BB, the connecting layer 102 covers surfaces of sides, away from the substrate 100, of the binding terminals 1 and extends to an area other than the binding terminals, and an orthographic projection of the connecting layer 102 on the substrate 100 partially overlaps with an orthographic projection of the part, located in the binding area BB, of the alignment layer PI on the substrate 100.

As shown in FIG. 3, a dotted box marked with an ACF refers to an area defined by an outer contour of the connecting layer after the connecting layer is formed. In addition, in FIG. 3, an area where the orthographic projection of the connecting layer overlaps with the orthographic projection of the alignment layer is filled with slashes, which is only described with an example.

Exemplarily, the connecting layer may be an ACF (anisotropic conductive film) and is used for electrically connecting the driver chip and the binding terminals together.

The material of the alignment layer is not limited herein. Exemplarily, the material of the alignment layer may be polyimide (PI). It should be noted that a structure marked with PI in the drawings provided in the embodiment of the present disclosure represents the alignment layer, but it is not proven that the material of the alignment layer can only be PI.

In some embodiments of the present disclosure, as shown in FIG. 3, the binding area BB includes a first binding subarea B1 and a second binding subarea B2, the first binding subarea B1 is located between the second binding subarea B2 and the active area AA, parts of the binding terminals are located in the first binding subarea B1, and parts of the binding terminals are located in the second binding subarea B2; wherein the orthographic projection of the connecting layer 102 such as the ACF on the substrate 100 overlaps with an orthographic projection of a part, located at a side where the first binding subarea B1 is away from the second binding subarea B2, of the alignment layer PI on the substrate 100.

In an exemplary embodiment, the binding terminals 1 in the first binding subarea B1 are output terminals, and the binding terminals 1 in the second binding subarea B2 are input terminals

Compared with an array base plate in the related art, in the embodiment of the present disclosure, the connecting layer is moved to a direction close to the active area AA, so that the orthographic projection of the connecting layer on the substrate partially overlaps with an orthographic projection of a part, located in the binding area, of the alignment layer on the substrate, a distance from the connecting layer to the edge of the active area along the direction parallel to the plane where the substrate is located and pointing from the active area to the binding area is reduced to a great extent, and then, a size of the binding area of the array base plate is reduced, thereby it is beneficial to the preparation of a display product with a narrow border frame.

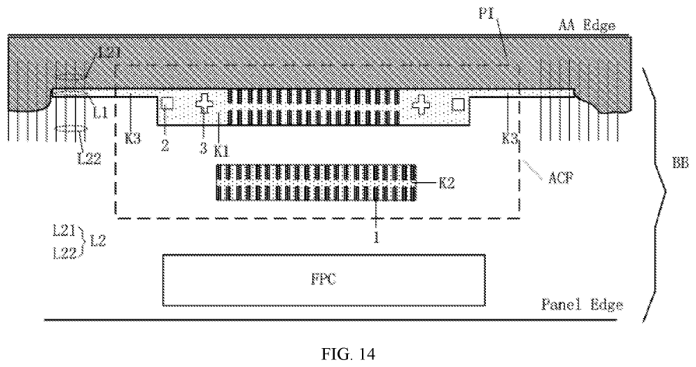

In some embodiments of the present disclosure, as shown in FIG. 5, FIG. 6, FIG. 10, and FIG. 14, the array base plate further includes a planarization layer 101 extending from the active area AA to the binding area BB, a part, disposed in the binding area BB, of the planarization layer 101 is located between the connecting layer 102 and the substrate 100; a part, located in the first binding subarea B1, of the planarization layer 101 is provided with a first groove K1, and a part, located in the second binding subarea B2, of the planarization layer 101 is provided with a second groove K2; the first groove K1 is disconnected from the second groove K2, all the binding terminals 1 in the first binding subarea B1 are located in the first groove K1, and all the binding terminals 1 in the second binding subarea B2 are located in the second groove K2.

As shown in FIG. 10 and FIG. 14, an area between an orthographic projection of an outer contour of the first groove K1 on the substrate 100 and an orthographic projection of an outer contour of the second groove K2 on the substrate 100 does not overlap with the orthographic projection of the alignment layer PI on the substrate 100.

In an exemplary embodiment, the planarization layer plays roles in insulation and planarization and is made of an organic insulating material, such as resin.

In some embodiments of the present disclosure, an area defined by the orthographic projections of the outer contours of all the grooves on the substrate 100 at least partially overlaps with the orthographic projection of the connecting layer 102 on the substrate 100, and the area defined by the orthographic projections of the outer contours of all the grooves on the substrate 100 does not overlap with the orthographic projection of the alignment layer PI on the substrate 100.

In an exemplary embodiment, in order to reduce a size from the edge of the array base plate to the edge of the active area, the alignment layer can be set to extend to the binding area. However, in subsequent processes required after the alignment layer is formed, all the binding terminals need to be bound together by means of the connecting layer and the driver chip. In view of a situation that the alignment layer may affect the stability of electric connection between the connecting layer for binding and the binding terminals, as shown in FIG. 10 and FIG. 14, the alignment layer PI is set to extend to a position near left and right sides of the first groove K1, however, the alignment layer PI cannot extend to an area between the first groove K1 and the second groove K2, in this way, the size of the border frame of the array base plate is reduced, the display product with the narrow border frame is favorably prepared, at the same time, the stability of conduction among the binding terminals, the connecting layer and the driver chip in the array base plate is ensured, and the reliability and quality of the display product are improved.

In the related art, on one hand, in order to achieve the narrow border frame, the alignment layer extends to the binding area, in the current process, a coating thickness of the alignment layer is 900 μm±300 μm, and the material of the alignment layer may flow to an area marked with a dotted elliptical circle in FIG. 4A along an edge of the first groove K1, so that the connecting layer at two sides of the first groove K1 is covered on the alignment layer; and on the other hand, when the connecting layer is formed and is pressed on upper surfaces of the binding terminals, in the related art, an area defined by the outer contour of the first groove K1 is much larger than an area where the binding terminals in the first groove K1 are located, the heights of the binding terminals located in the first groove K1 are higher, the heights of conductive patterns (such as a first alignment marking pattern 2 and a second alignment marking pattern 3) located in the first groove K1 are lower, there are height differences therebetween, and therefore, when a pressure head applies a pressure to the connecting layer, the connecting layer in an area K1-3 as shown in FIG. 4B is easily stressed, and this part of the connecting layer is in tight contact with the binding terminals, the connecting layer in an area K1-1 and an area K1-2 as shown in FIG. 4B is not easily stressed, and this part of the connecting layer is not in sufficient contact and adhesion to the conductive patterns or substrate. FIG. 4B is a sectional diagram of FIG. 4A along an M1M12 direction.

During the processes of later use and tests of the display product, on one hand, the connecting layer itself close to a side wall of the first groove K1 is weaker in adhesion, and on the other hand, the connecting layer at two sides of the first groove K1 is covered on the alignment layer, and due to a water absorption characteristic of the material of the alignment layer, the adhesion of the connecting layer on the edge of the first groove K1 is further weakened, and therefore, when a reliability test (under the conditions of high temperature and high humidity) is performed on a display apparatus prepared by using the array base plate, the connecting layer in a local area is stripped, which finally results in poor conduction between the binding terminals and the driver chip and abnormal display of the display apparatus.

Based on this, the problem of abnormal display caused by poor conduction can be relieved by improving the adhesion between the connecting layer and a bottom film layer or preventing the material of the alignment layer from flowing to the area shown as the dotted elliptical circle in FIG. 4A.

The embodiment of the present disclosure provides a solution that the first groove K1 is inwards shrunk in FIG. 5 or a solution that two sides of the first groove K1 are provided with third grooves K3 extending outwards in FIG. 11 for improvement.

In some embodiments of the present disclosure, as shown in FIG. 11, the planarization layer 101 is further provided with third grooves K3, the third grooves communicates with the first groove K1, the third grooves K3 extend along a direction away from the first binding subarea B1 along a first direction OA, and the first direction OA is perpendicular to a direction pointing from the active area AA to the binding area BB; and along the direction pointing from the active area AA to the binding area BB, sizes h2 of orthographic projections of the third grooves K3 on the substrate 100 are less than a size h1 of an orthographic projection of the first groove K1 on the substrate 100.

In an exemplary embodiment, the size h1 of the orthographic projection of the first groove K1 on the substrate 100 can be co-determined according to sizes of all the binding terminals 1 in the first binding subarea B1, an arrangement way of all the binding terminals 1 and distances among all the binding terminals to ensure that all the binding terminals in the first binding subarea B1 are located in the first groove K1, which is not limited herein.

In an exemplary embodiment, when the third grooves K3 are disposed, specific data of the sizes h2 of the orthographic projections of the third grooves K3 on the substrate 100 is not limited herein, and can be specifically determined according to a size of an actual design space.

Exemplarily, in order to save a design space, a range of the sizes h2 of the orthographic projections of the third grooves K3 on the substrate 100 can be 20 μm±5 μm.

It should be noted that all the grooves provided in the embodiment of the present disclosure are disposed on the planarization layer PLN, and the planarization layer plays roles in insulation and planarization in a partial area. The partial area of the planarization layer needs to be provided with an opening to expose a film layer structure on a bottom layer for electric connection, and therefore, all the grooves disposed on the planarization layer related to the inventiveness of the present disclosure are through grooves. Of course, other areas of the planarization layer of the array base plate can also be provided with non-through grooves, which can be specifically determined according to an actual situation.

In some embodiments of the present disclosure, as shown in FIG. 11, the area defined by the orthographic projection of the outer contour of the first groove K1 on the substrate 100 and the area defined by the orthographic projection of the outer contour of the second groove K2 on the substrate 100 are both located in the orthographic projection of the connecting layer (such as the ACF) on the substrate 100; and an area defined by orthographic projections of outer contours of the third grooves K3 on the substrate 100 partially overlaps with the orthographic projection of the connecting layer (such as the ACF) on the substrate 100.

In the embodiment of the present disclosure, by disposing the communicating third grooves K3 at two sides of the first groove K1, in an actual preparation process, the communicating grooves play a role in blocking the material of the alignment layer, so that the material of the alignment layer flows along an edge of a large groove (a groove formed after the first groove K1 communicates with the third grooves K3), and finally, the alignment layer is located at a side, close to the active area, of the large groove. Even if the connecting layer itself close to the side wall of the first groove K1 is weaker in adhesion, the alignment layer at two sides of the large groove is farther from the binding terminals in the first groove K1 and the alignment layer at two sides of the large groove is farther from the two sides of the first groove K1, and thus, impacts of the water absorption characteristic of the material of the alignment layer on the connecting layer near the binding terminals 1 are weakened. When a reliability test (under the conditions of high temperature and high humidity) is performed on a display apparatus prepared by using the array base plate, the adhesion of the connecting layer is weakened to a smaller extent, the conduction between the binding terminals and the driver chip is normal, and the display effect of the display apparatus is improved.

In addition, the area defined by the orthographic projections of the outer contours of the third groove K3 on the substrate 100 is set to partially overlap with the orthographic projection of the connecting layer (such as the ACF) on the substrate 100, and an area defined by orthographic projections of ends, away from the first groove K1, of the third grooves K3 on the substrate 100 does not overlap with the orthographic projection of the connecting layer (such as the ACF) on the substrate 100. In this way, even if the material of the alignment layer bypasses the ends, away from the first groove K1, of the third grooves K3 to flow to the first groove K1, the area defined by the orthographic projections of the ends, away from the first groove K1, of the third grooves K3 on the substrate 100 does not overlap with the orthographic projection of the connecting layer (such as the ACF) on the substrate 100, which reduces a probability that the material of the alignment layer flows into an area where the connecting layer (such as the ACF) is located along a direction indicated by an arrow shown in FIG. 11 to a great extent, so that the impacts of the water absorption characteristic of the material of the alignment layer on the adhesion of the connecting layer are reduced, a probability of poor conduction between the connecting layer and the binding terminals is reduced, and the reliability of the array base plate is further improved.

In some embodiments of the present disclosure, along a direction parallel to the plane where the substrate 100 is located and along the first direction OA, the minimum distance h3 from the ends, away from the first groove K1, of the third grooves K3 to an edge of the connecting layer is greater than or equal to 300 μm, and is less than or equal to 800 μm.

Exemplarily, sizes of the third grooves K3 along the first direction OA may be about one 1000 μm.

In the embodiment of the present disclosure, when the material of the alignment layer flows along the outer contours of the third grooves K3, even if the material of the alignment layer bypasses the ends, away from the first groove K1, of the third grooves K3 to flow to the connecting layer located between the first binding subarea B1 and the second binding subarea B2, the minimum distance h3 from the ends, away from the first groove K1, of the third grooves K3 to the edge of the connecting layer is greater than or equal to 300 μm, which makes it difficult for the material of the alignment layer to flow to the edge of the connecting layer located between the first binding subarea B1 and the second binding subarea B2, so that adverse impacts of the material of the alignment layer on the connecting layer are avoided, and the stability of electric connection between the binding terminals of the array base plate and the driver chip by using the connecting layer is improved.

In addition, in order to avoid interference of the third grooves K3 on the arrangement design of wrings of the array base plate, the minimum distance h3 from the ends, away from the first groove K1, of the third grooves K3 to the edge of the connecting layer is set to be less than or equal to 800 μm, so that the design is simplified, and the difficulty in preparation process is lowered.

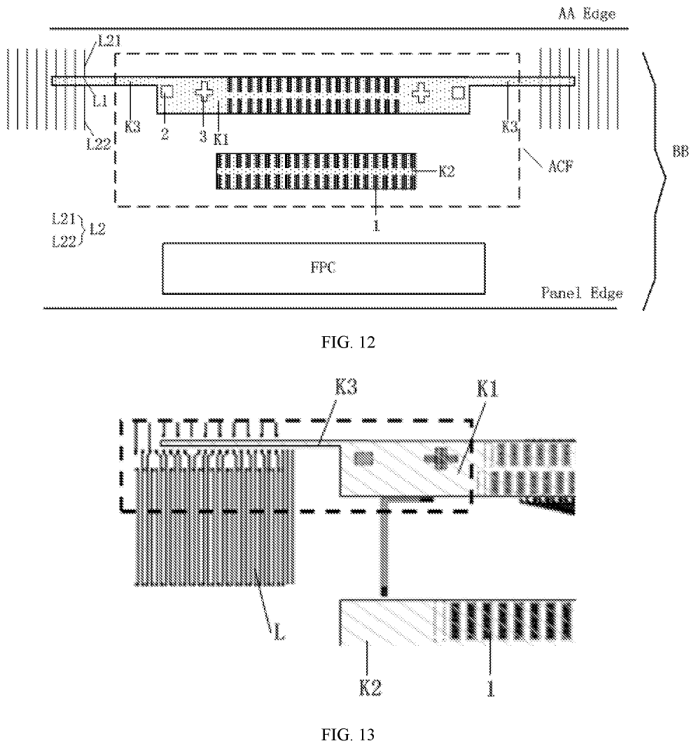

In some embodiments of the present disclosure, as shown in FIG. 12, FIG. 13, and FIG. 14, the array base plate further includes connecting wrings L and a fan-out area located between the active area AA and the binding area BB, the connecting wrings L extend from the fan-out area to the binding area, parts, located in the binding area BB, of the connecting wrings L are disposed in areas other than the first binding subarea B1 and the second binding subarea B2 in the binding area BB, and the connecting wrings L are electrically connected to the binding terminals 1; and the area defined by the orthographic projections of the outer contours of the third grooves K3 on the substrate 100 overlaps with orthographic projections of parts of the connecting wrings L on the substrate 100.

In an exemplary embodiment, the extending directions of the connecting wrings L and a specific way of electric connection between the connecting wrings L and the binding terminals 1 are not limited herein, and can be specifically determined according to an actual line arrangement design.

In some embodiments of the present disclosure, the array base plate further includes a gate layer and a source-drain metal layer, the gate layer is insulated from the source-drain metal layer; the source-drain metal layer is located between the planarization layer and the substrate, and the gate layer is located between the source-drain metal layer and the substrate; as shown in FIG. 12, parts of the connecting wrings L include first line segments L1 and second line segments L2, the first line segments L1 are located at the gate layer Gate, and the second line segments L2 are located in the source-drain metal layer SD;
wherein orthographic projections of the first line segments L1 on the substrate 100 are located in the area defined by the orthographic projections of the outer contours of the third grooves K3 on the substrate 100, orthographic projections of the second line segments L2 on the substrate 100 are located out of the area defined by the orthographic projections of the outer contours of the third grooves K3 on the substrate 100, and the first line segments L1 are electrically connected to the second line segment L2.

In the embodiment of the present disclosure, a film layer in the array base plate includes the gate layer, a gate insulation layer, the source-drain metal layer, the planarization layer 101, a pixel electrode layer and the connecting layer 102 sequentially disposed on the substrate 100, wherein when the connecting wrings L in FIG. 12 are located on the source-drain metal layer, the third grooves K3 will expose partial areas overlapping with the connecting wrings L, a partial area of the source-drain metal layer will be exposed outside to be corroded, and therefore, in the array base plate provided in the embodiment of the present disclosure, the first line segments L1 of which the orthographic projections are located in the area defined by the orthographic projections of the outer contours of the third grooves K3 on the substrate 100 are set to be located on the gate layer. By means of a jumper design, the first line segments L1 located on the gate layer are electrically connected to the second line segments L2 located on the source-drain metal layer SD through via holes in the gate insulation layer, so that the situation that the third grooves K3 are disposed to corrode the connecting wrings L is avoided, and the reliability and quality of the array base plate are improved. It should be noted that, for simplifying the design, all the via holes for connecting the first line segments L1 and the second line segments L2 are disposed in positions overlapping with the projections of the second line segments L2 to keep away from areas where the third grooves K3 are located, so that the difficulty in design and preparation process is reduced.

In addition, it should be further noted that when all the connecting wrings L in FIG. 12 are located on the gate layer, the gate layer is provided with the gate insulation layer for protection, the planarization layer is provided with the third grooves K3 to avoid exposing the connecting wrings, so that the jumper design can be omitted.

The binding terminals 1 include three sub-layers. Specifically, along a direction away from the substrate, the three sub-layers are respectively and sequentially located on the gate layer, the source-drain metal layer and the pixel electrode layer, which can be specifically referred to the related art so as to be no longer repeated herein.

In some embodiments of the present disclosure, as shown in FIG. 12, the second line segments L2 include first subline segments L21 and second subline segments L22, the orthographic projections of the first line segments L1 on the substrate 100 are located between orthographic projections of the first subline segments L21 on the substrate 100 and orthographic projections of the second subline segments L22 on the substrate 100; and the first subline segments L21 are electrically connected to the second subline segments L22 by using the first line segments L1;
wherein as shown in FIG. 14, the second subline segments L22 are located at sides, away from the active area AA, of the first subline segments L21, and the orthographic projection of the alignment layer PI on the substrate 100 overlaps with the orthographic projections of the first subline segments L21 on the substrate 100, and the orthographic projection of the alignment layer PI on the substrate 100 does not overlap with orthographic projections of at least part of the second subline segments L22 on the substrate 100.

In an exemplary embodiment, the orthographic projection of the alignment layer PI on the substrate 100 does not overlap with the orthographic projections of the at least parts of the second subline segments L22 on the substrate 100, which includes the following situation:
the orthographic projection of the alignment layer PI on the substrate 100 does not overlap with the orthographic projections of the at least part of the second subline segments L22 on the substrate 100;
or, the orthographic projection of the alignment layer PI on the substrate 100 does not overlap with orthographic projections of the second subline segments L22 on the substrate 100.

In some embodiments of the present disclosure, as shown in FIG. 11 to FIG. 14, the array base plate further includes at least one conductive pattern (such as a first alignment marking pattern 2 and a second alignment marking pattern 3), the at least one conductive pattern is located between the binding terminals 1 and the connecting wrings L, and orthographic projections of the conductive patterns on the substrate 100 are located in the area defined by the orthographic projection of the outer contour of the first groove K1 on the substrate 100.

In the embodiment of the present disclosure, referring to FIG. 11 to FIG. 14, by disposing the communicating third grooves K3 at two sides of the first groove K1, in an actual preparation process, the communicating grooves play a role in blocking the material of the alignment layer, so that the material of the alignment layer flows along an edge of a large groove (a groove formed after the first groove K1 communicates with the third grooves K3), and finally, the alignment layer is located at a side, close to the active area, of the large groove. Even if the connecting layer itself close to the side wall of the first groove K1 is weaker in adhesion, the alignment layer at two sides of the large groove is farther from the binding terminals in the first groove K1 and the alignment layer at two sides of the large groove is farther from the two sides of the first groove K1, and thus, impacts of the water absorption characteristic of the material of the alignment layer on the connecting layer near the binding terminals 1 are weakened. When a reliability test (under the conditions of high temperature and high humidity) is performed on the array base plate, the adhesion of the connecting layer is weakened to a smaller extent, the conduction between the binding terminals and the driver chip is normal, and the display effect of a display apparatus prepared by using the array base plate is improved.

In some embodiments of the present disclosure, as shown in FIG. 5 to FIG. 10, the area defined by the orthographic projections of the outer contours of all the grooves (such as K1, K2 and K4) on the substrate 100 is located in the orthographic projection of the connecting layer (such as the ACF) on the substrate 100.

In some embodiments of the present disclosure, as shown in FIG. 5, the minimum distance from the binding terminals 1 arranged along a side wall of the first groove K1 in the first binding subarea B1 to the side wall of the first groove K1 is less than or equal to a first preset value, the minimum distance from the binding terminals 1 arranged along a side wall of the second groove K2 in the second binding subarea B2 to the side wall of the second groove K2 is less than or equal to a first preset value, and the first present value is a process deviation value.

A specific value of the process deviation value is not limited herein, and the process deviation value may be different according to different devices and different process stability, and can be specifically determined according to an actual situation.

It can be understood that a size of the first groove K1 is reduced as much as possible under the condition that the first groove K1 can contain the binding terminals 1 located in the first binding subarea B1, and a size of the second groove K2 is reduced as much as possible under the condition that the second groove K2 can contain all the binding terminals 1 located in the second binding subarea B2. In this way, as shown in FIG. 6, when the connecting layer is formed and a force is applied to the connecting layer, there are no areas marked as K1-1 and K1-2 as shown in FIG. 4 and padded by the binding terminals 1 to be empty in the related art, so that a better adhesion is formed between the connecting layer and the binding terminals 1 in the first groove K1 and the second groove K2, and the stability of conduction between the connecting layer 102 and the binding terminals 1 is improved. Therefore, even if the material of the alignment layer flows into the areas at the left and right sides of the first groove K1 to result in adverse impacts on the connecting layer 102 due to the water absorption characteristic of the material of the alignment layer, the connecting layer 102 cannot be separated from the binding terminals 1, so that the reliability and quality of the array base plate are improved.

In some embodiments of the present disclosure, as shown in FIG. 6, a distance h4 from a surface, away from the substrate 100, of a part, covering the binding terminals 1, of the connecting layer 102 to the substrate 100 along a direction perpendicular to the plane where the substrate 100 is located is less than a distance h5 from a surface, away from the substrate 100, of the rest part of the connecting layer 102 to the substrate 100 along the direction perpendicular to the plane where the substrate 100 is located. FIG. 6 is a sectional diagram of FIG. 5 along an M3M4 direction.

In an exemplary embodiment, under the condition that the grooves (including the first groove K1 and the second groove K2) are only disposed in the areas (such as the first binding subarea B1 and the second binding subarea B2) where the binding terminals are located, the minimum distance from the binding terminals 1 arranged along the side wall of the first groove K1 in the first binding subarea B1 to the side wall of the first groove K1 is less than or equal to the first preset value, the minimum distance from the binding terminals 1 arranged along the side wall of the second groove K2 in the second binding subarea B2 to the side wall of the second groove K2 is less than or equal to the first preset value, and the first present value is the process deviation value. Then, under the condition that a process deviation is not taken into account, it can be understood that a distance from an upper surface of the connecting layer 102 in the areas where the binding terminals 1 are disposed to the substrate 100 is less than a distance from an upper surface of the connecting layer 102 in other areas where the binding terminals are not disposed to the substrate 100. In this way, during a binding process, there is a stronger adhesion between the connecting layer 102 and the binding terminals located in the grooves, and then, the stability of conduction between the connecting layer 102 and the binding terminals 1 is improved. Therefore, even if the material of the alignment layer flows into the areas at the left and right sides of the first groove K1 to result in adverse impacts on the connecting layer 102 due to its water absorption characteristic, the connecting layer 102 cannot be separated from the binding terminals 1, so that the reliability and quality of the array base plate are improved.

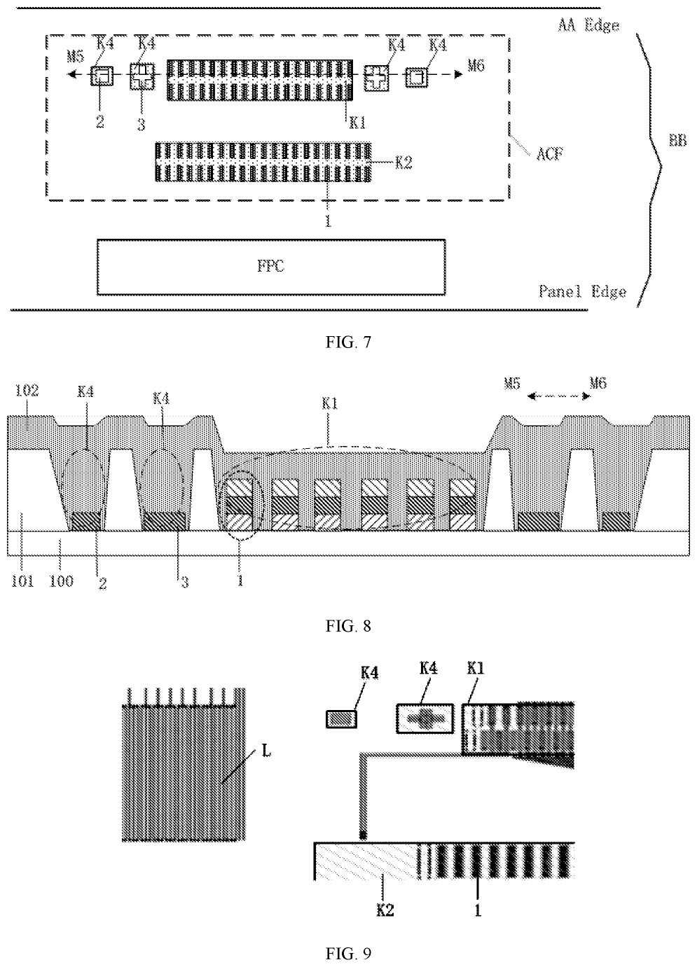

In some embodiments of the present disclosure, as shown in FIG. 7, FIG. 8 and FIG. 9, the planarization layer 101 is further provided with at least one fourth groove K4, the at least one fourth groove K4 is disconnected from the first groove K1, the array base plate further includes at least one conductive pattern located in the binding area BB, one of the conductive patterns is disposed in one of the at least one fourth groove K4, and a distance from the conductive pattern to a side wall of the fourth groove K4 is less than or equal to the first preset value. FIG. 8 is a sectional diagram of FIG. 7 along an M5M6 direction.

In an exemplary embodiment, the conductive patterns may include alignment marking patterns, such as a first alignment marking pattern 2 and a second alignment marking pattern 3.

In an exemplary embodiment, the conductive patterns may further include a Dummy pattern or other conductive islands.

In an exemplary embodiment, the conductive patterns may be located at the source-drain metal layer, for example, the alignment marking patterns are located at the source-drain metal layer.

In an exemplary embodiment, the conductive patterns may be located at the gate layer.

In some embodiments of the present disclosure, as shown in FIG. 7, FIG. 9 and FIG. 10, the planarization layer 101 is provided with two fourth grooves K4 located at a same side of the first groove K1, and a direction pointing from the first groove K1 to each of the two fourth grooves K4 is perpendicular to the direction pointing from the active area AA to the binding area BB; and an orthographic projection of a part, located between two adjacent fourth grooves K4, of the planarization layer 101 on the substrate 100 overlaps with the orthographic projection of the alignment layer PI on the substrate 100.

For an edge contour of the alignment layer as shown in FIG. 10, under the condition that the fourth grooves K4 are disposed in the binding area, the material of the alignment layer flows along edge contours of the grooves, so that the alignment layer is disposed in an area between the two adjacent grooves, such as between the two adjacent fourth grooves K4 and between adjacent first groove K1 and fourth groove K4. In this way, a size of a border frame at a side where the binding area of the array base plate is located can be reduced to a great extent, thereby it is beneficial to realize the preparation of a product with an extremely narrow border.

A display apparatus is provided by an embodiment of the present disclosure, which includes the array base plate mentioned as above.

A specific structure of the array base plate included by the display apparatus is not repeated herein, and can specifically be referred to the above description.

The display apparatus provided in the embodiment of the present disclosure is a liquid crystal display (LCD). In addition, the display apparatus may be a display device such as an LCD as well as any product or component with a display function, such as a television, a digital camera, a mobile phone and a tablet personal computer including the display device.

Exemplarily, the above-mentioned display apparatus is a liquid crystal display in an advanced super dimension switch (ADS) display mode, wherein an ADS is a general term of core technologies represented by a wide-view technology.

Compared with a display apparatus in the related art, in the embodiment of the present disclosure, the connecting layer is moved to a direction close to the active area AA, so that the orthographic projection of the connecting layer on the substrate partially overlaps with an orthographic projection of a part, located in the binding area, of the alignment layer on the substrate, a distance from the connecting layer to the edge of the active area along the direction parallel to the plane where the substrate is located and pointing from the active area to the binding area is reduced to a great extent, and then, a size of the binding area of the display apparatus is reduced, thereby it is beneficial to the preparation of a display product with a narrow border frame.

In addition, during the processes of later use and tests of the display product, on one hand, the connecting layer itself close to a side wall of the first groove K1 is weaker in adhesion, and on the other hand, the connecting layer at two sides of the first groove K1 is covered on the alignment layer, and due to a water absorption characteristic of the material of the alignment layer, the adhesion of the connecting layer on the edge of the first groove K1 is further weakened, and therefore, when a reliability test (under the conditions of high temperature and high humidity) is performed on a display apparatus prepared by using the array base plate, the connecting layer in a local area is stripped, which finally results in poor conduction between the binding terminals and the driver chip and abnormal display of the display apparatus prepared by using the array base plate.

According to the display apparatus provided in the embodiment of the present disclosure, the problem of abnormal display caused by poor conduction can be relieved by improving the adhesion between the connecting layer and a bottom film layer or preventing the material of the alignment layer from flowing to the area shown as the dotted elliptical circle in FIG. 4A.

In some embodiments of the present disclosure, the display apparatus further includes a driver chip IC, the driver chip IC is electrically connected to the binding terminals 1 by using the connecting layer 102, the connecting layer 102 includes an anisotropic conductive film, and an orthographic projection of the driver chip IC on the substrate 100 is located in the orthographic projection of the connecting layer 102 on the substrate 100.

In an exemplary embodiment, the driver chip IC may be a touch and display driver integration (TDDI) chip or non-TDDI chip.

In an exemplary embodiment, the orthographic projection of the driver chip IC on the substrate 100 is located in the orthographic projection of the connecting layer 102 on the substrate 100, which includes the following situation:
an outer contour of the orthographic projection of the driver chip IC on the substrate 100 is located in an outer contour of the orthographic projection of the connecting layer 102 on the substrate 100;
or, the outer contour of the orthographic projection of the driver chip IC on the substrate 100 overlaps with the outer contour of the orthographic projection of the connecting layer 102 on the substrate 100.

In some embodiments of the present disclosure, the display apparatus further includes an flexible printed circuit, the flexible printed circuit is electrically connected to a binding electrode on the array base plate by using a conductive layer, and the conductive layer includes an anisotropic conductive film.

In an exemplary embodiment, the binding electrode is used for electric connection between the array base plate and the flexible printed circuit. The binding terminal mentioned above is used for electric connection between the array base plate and the driver chip. In the drawings provided in the embodiment of the present disclosure, the structure of the binding electrode is not embodied.

Exemplarily, a film layer structure of the binding electrode may be similar to that of each of the binding terminals, and can specifically be referred to the related description for the binding terminals mentioned above.

In addition, the function of the conductive layer is similar to the function of the connecting layer mentioned above, and the conductive layer and the connecting layer can be both the anisotropic conductive film.

In some embodiments of the present disclosure, the display apparatus further includes an opposite base plate, the opposite base plate is opposite to the array base plate, and an orthographic projection of the opposite base plate on the substrate does not overlap with the binding area.

In an exemplary embodiment, the orthographic projection of the opposite base plate on the substrate partially overlap with the orthographic projection of the array base plate on the substrate, and the opposite base plate is exposed out of a partial structure, located in the binding area, of the array base plate, so that the driver chip and the flexible printed circuit can be disposed in the binding area to transmit a driving signal to the array base plate in the display apparatus.

The above descriptions are only specific implementations of the present disclosure, but the protection scope of the present disclosure is not limited thereto. Any variations or replacements that can be readily envisioned by those skilled in the art within the technical scope disclosed by the present disclosure should fall within the protection scope of the present disclosure. Therefore, the protection scope of the present disclosure should be subject to the protection scope defined in the claims.

1. An array base plate, comprising a substrate, an active area and a binding area that are located on the substrate, wherein the binding area is located at one side of the active area;
the array base plate further comprising:
an alignment layer extending from the active area to the binding area; and
binding terminals located in the binding area, wherein an orthographic projection of the alignment layer on the substrate does not overlap with orthographic projections of the binding terminals on the substrate;
wherein in a direction parallel to a plane where the substrate is located and pointing from the active area to the binding area, a minimum distance from the binding terminals to an edge of the active area is less than or equal to a maximum distance from an edge of a part, located in the binding area, of the alignment layer to the edge of the active area.

2. The array base plate according to claim 1, wherein the array base plate comprises a connecting layer located in the binding area, the connecting layer covers surfaces of sides of the binding terminals away from the substrate, and extends to an area other than the binding terminals, and an orthographic projection of the connecting layer on the substrate partially overlaps with an orthographic projection of the part, located in the binding area, of the alignment layer on the substrate.

3. The array base plate according to claim 2, wherein the binding area comprises a first binding subarea and a second binding subarea, the first binding subarea is located between the second binding subarea and the active area, parts of the binding terminals are located in the first binding subarea, and parts of the binding terminals are located in the second binding subarea;
wherein the orthographic projection of the connecting layer on the substrate overlaps with an orthographic projection of a part, located at a side where the first binding subarea is away from the second binding subarea, of the alignment layer on the substrate.

4. The array base plate according to claim 3, wherein the array base plate further comprises a planarization layer extending from the active area to the binding area, a part, disposed in the binding area, of the planarization layer is located between the connecting layer and the substrate; a part, located in the first binding subarea, of the planarization layer is provided with a first groove, and a part, located in the second binding subarea, of the planarization layer is provided with a second groove;
the first groove is disconnected from the second groove, all the binding terminals in the first binding subarea are located in the first groove, all the binding terminals in the second binding subarea are located in the second groove, and an area between an orthographic projection of an outer contour of the first groove on the substrate and an orthographic projection of an outer contour of the second groove on the substrate does not overlap with the orthographic projection of the alignment layer on the substrate.

5. The array base plate according to claim 4, wherein an area defined by orthographic projections of outer contours of all grooves on the substrate at least partially overlaps with the orthographic projection of the connecting layer on the substrate, and the area defined by the orthographic projections of the outer contours of all the grooves on the substrate does not overlap with the orthographic projection of the alignment layer on the substrate.

6. The array base plate according to claim 5, wherein the planarization layer is further provided with third grooves, the third grooves communicate with the first groove, the third grooves extend along a direction away from the first binding subarea along a first direction, and the first direction is perpendicular to a direction pointing from the active area to the binding area; and along the direction pointing from the active area to the binding area, sizes of orthographic projections of the third grooves on the substrate are less than a size of an orthographic projection of the first groove on the substrate.

7. The array base plate according to claim 6, wherein the area defined by the orthographic projection of the outer contour of the first groove on the substrate and the area defined by the orthographic projection of the outer contour of the second groove on the substrate are both located in the orthographic projection of the connecting layer on the substrate; and
an area defined by orthographic projections of outer contours of the third grooves on the substrate partially overlaps with the orthographic projection of the connecting layer on the substrate.

8. The array base plate according to claim 7, wherein along a direction parallel to the plane where the substrate is located and along the first direction, a minimum distance from ends, away from the first groove, of the third grooves to an edge of the connecting layer is greater than or equal to 300 μm and is less than or equal to 800 μm.

9. The array base plate according to claim 7, wherein the array base plate comprises a fan-out area located between the active area and the binding area; the array base plate further comprises connecting wrings, the connecting wrings extend from the fan-out area to the binding area, parts, located in the binding area, of the connecting wrings are disposed in areas other than the first binding subarea and the second binding subarea in the binding area, and the connecting wrings are electrically connected to the binding terminals; and the area defined by the orthographic projections of the outer contours of the third grooves on the substrate overlaps with orthographic projections of parts of the connecting wrings on the substrate.

10. The array base plate according to claim 9, wherein the array base plate further comprises a gate layer and a source-drain metal layer, the gate layer is insulated from the source-drain metal layer; the source-drain metal layer is located between the planarization layer and the substrate, and the gate layer is located between the source-drain metal layer and the substrate;
parts of the connecting wrings comprise first line segments and second line segments, the first line segments are located at the gate layer, and the second line segments are located at the source-drain metal layer;
wherein orthographic projections of the first line segments on the substrate are located in the area defined by the orthographic projections of the outer contours of the third grooves on the substrate, orthographic projections of the second line segments on the substrate are located out of the area defined by the orthographic projections of the outer contours of the third grooves on the substrate, and the first line segments are electrically connected to the second line segments.

11. The array base plate according to claim 10, wherein the second line segments comprise first subline segments and second subline segments, the orthographic projections of the first line segments on the substrate are located between orthographic projections of the first subline segments on the substrate and orthographic projections of the second subline segments on the substrate; and the first subline segments are electrically connected to the second subline segments by using the first line segments;
wherein the second subline segments are located at sides, away from the active area, of the first subline segments, and the orthographic projection of the alignment layer on the substrate overlaps with the orthographic projections of the first subline segments on the substrate, and the orthographic projection of the alignment layer on the substrate does not overlap with orthographic projections of at least part of the second subline segments on the substrate.

12. The array base plate according to claim 9, wherein the array base plate further comprises at least one conductive pattern, the at least one conductive pattern is located between the binding terminals and the connecting wrings, and an orthographic projection of the at least one conductive pattern on the substrate is located in the area defined by the orthographic projection of the outer contour of the first groove on the substrate.

13. The array base plate according to claim 5, wherein the area defined by the orthographic projections of the outer contours of all the grooves on the substrate is located in the orthographic projection of the connecting layer on the substrate.

14. The array base plate according to claim 13, wherein a minimum distance from all the binding terminals arranged along a side wall of the first groove in the first binding subarea to the side wall of the first groove is less than or equal to a first preset value, a minimum distance from all the binding terminals arranged along a side wall of the second groove in the second binding subarea to the side wall of the second groove is less than or equal to the first preset value, and the first present value is a process deviation value.

15. The array base plate according to claim 14, wherein a distance from a surface, away from the substrate, of a part, covering the binding terminals, of the connecting layer to the substrate along a direction perpendicular to the plane where the substrate is located is less than a distance from a surface, away from the substrate, of the rest part of the connecting layer to the substrate along the direction perpendicular to the plane where the substrate is located.

16. The array base plate according to claim 14, wherein the planarization layer is further provided with at least one fourth groove, the at least one fourth groove is disconnected from the first groove, the array base plate further comprises at least one conductive pattern located in the binding area, one conductive pattern is disposed in one fourth groove, and a distance from the at least one conductive pattern to a side wall of each of the at least one fourth groove is less than or equal to the first preset value.

17. The array base plate according to claim 16, wherein the planarization layer is provided with two fourth grooves located at a same side of the first groove, and a direction pointing from the first groove to each of the two fourth grooves is perpendicular to the direction pointing from the active area to the binding area; and
an orthographic projection of a part, located between two adjacent fourth grooves, of the planarization layer on the substrate overlaps with the orthographic projection of the alignment layer on the substrate.

18. A display apparatus, comprising the array base plate according to claim 1.

19. The display apparatus according to claim 18, wherein the display apparatus further comprises a driver chip, the driver chip is electrically connected to the binding terminals by using the connecting layer, the connecting layer comprises an anisotropic conductive film, and an orthographic projection of the driver chip on the substrate is located in the orthographic projection of the connecting layer on the substrate.

20. The display apparatus according to claim 18, wherein the display apparatus further comprises a flexible printed circuit, the flexible printed circuit is electrically connected to a binding electrode on the array base plate by using a conductive layer, and the conductive layer comprises an anisotropic conductive film.

21. (canceled)
